(19) United States
(12) Patent Application Publication
(10) Pub. No.: US 2025/0159833 A1
(43) Pub. Date: May 15, 2025

(54) POSITIONING STRUCTURE FOR SERVER, RACK AND COMPUTING DEVICE

(71) Applicant: Fulian Precision Electronics (Tianjin) Co., LTD., Tianjin (CN)

(72) Inventors: HUNG-WEI CHEN, New Taipei (TW); TZU-YAO WENG, New Taipei (TW)

(21) Appl. No.: 18/925,230

(22) Filed: Oct. 24, 2024

(30) Foreign Application Priority Data
Nov. 9, 2023 (CN) 202311492439.6

(51) Int. Cl. H05K 7/14; H05K 5/02; H05K 5/03

(52) U.S. Cl. CPC H05K 7/1489; H05K 5/0221; H05K 5/023; H05K 5/03

(57) ABSTRACT

A positioning structure for server includes a chassis, a door, a locking piece, a first elastic piece, and a handle. The chassis defines a cavity and a first opening. The door is rotatably connected to the chassis. The locking piece is movably connected to the door. The first elastic piece is connected to the locking piece and the door. The handle is movably connected to the door. When the door covers the first opening, the first elastic piece moves the locking piece into a slot of the chassis to position the door, when the door covers the first opening and the handle moves away from the chassis, the locking piece moves out of the slot to allow the door to open the first opening. A server and a computing device with the positioning structure are also disclosed.

### FIELD

The disclosure herein generally relates to information computing systems, and more particularly relates to a positioning structure for server, a rack, and a computing device.

### BACKGROUND

Servers are installed in a rack in layers, and the servers usually are positioned in the chassis of the rack, and a door is provided on the chassis to allow the servers to enter and exit the chassis. The door is generally a push-to-open door, so users can open the door by pressing, but users may accidentally press the door, causing the door to open and exposing the server.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings like reference numerals designate corresponding parts throughout the several views.

FIG. 1 is an isometric view of an embodiment of a rack of a computing device according to the present disclosure.

FIG. 2 is an isometric view of a positioning structure according to the present disclosure.

FIG. 3 is an isometric view of a door shown in FIG. 1.

FIG. 4 is an exploded view of the door shown in FIG. 3.

FIG. 5 is an isometric view of a chassis shown in FIG. 1.

FIG. 6 is an isometric view of a sliding piece shown in FIG. 1.

FIG. 7 is an isometric view of the door shown in FIG. 3, showing the door opens at a first opening.

FIG. 8 is a cross-section view along VIII-VIII in FIG. 3.

FIG. 9 is a cross-section view showing a handle moves a locking piece out of a slot according to the present disclosure.

FIG. 10 is a cross-section view showing the locking piece in FIG. 9 out of the slot.

FIG. 11 is an isometric view of the locking piece and a second rotating board according to the present disclosure.

FIG. 12 is an exploded view of the locking piece and the handle according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, baffle structures, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The present disclosure, including the accompanying drawings, is illustrated by way of examples and not by way of limitation. Several definitions that apply throughout this disclosure will now be presented. It should be noted that references to “an” or “one” embodiment in this disclosure are not necessarily to the same embodiment, and such references mean “at least one”.

The term “comprising” means “including, but not necessarily limited to;” it specifically indicates open-ended inclusion or membership in a so-described combination, group, series, and the like.

Without a given definition otherwise, all terms used have the same meaning as commonly understood by those skilled in the art. The terms used herein in the description of the present disclosure are for the purpose of describing specific embodiments only, and are not intended to limit the present disclosure.

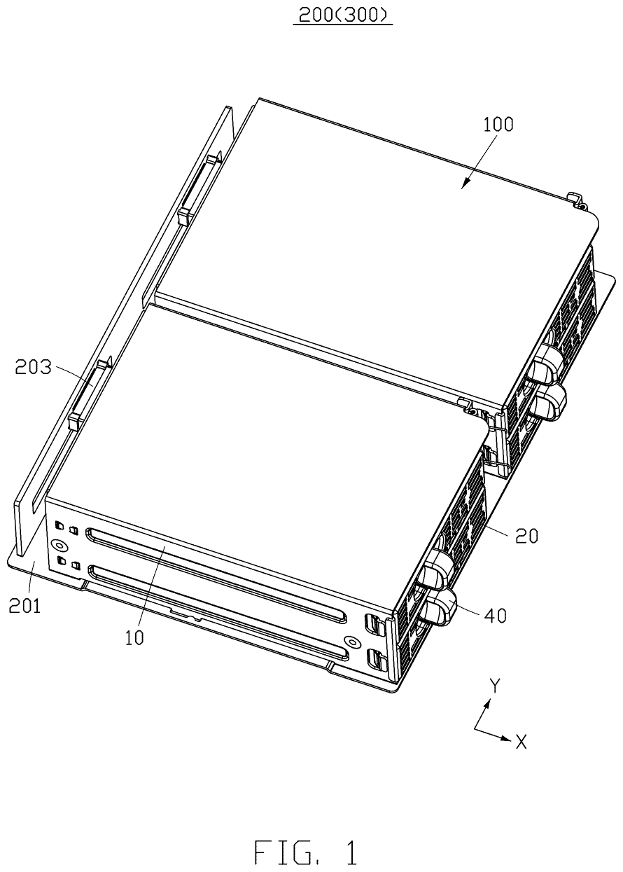

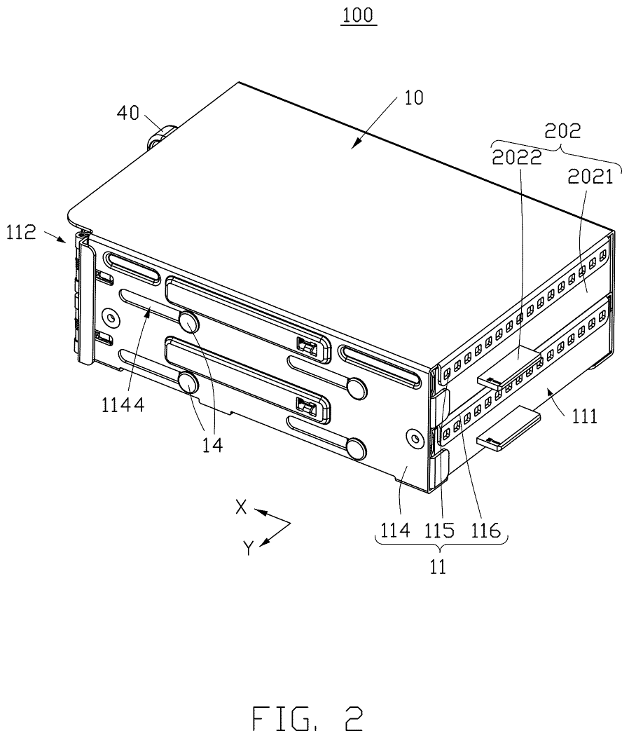

As shown in FIG. 1 and FIG. 2, a computing device 300 in an embodiment includes a rack 200 and a plurality of servers 202. The rack 200 includes a rack body 201 and a plurality of positioning structures 100. The positioning structures 100 are located on the rack body 201. Each positioning structure 100 is used for positioning a server 202 to the rack body 201.

As shown in FIG. 1 and FIG. 2, in some embodiments, the rack 200 further includes connectors 203 located on the rack body 201. When installing a server 202 to a positioning structure 100, the server 202 will be connected to a connector 203.

As shown in FIG. 1 and FIG. 2, in some embodiments, each server 202 includes a storage module 2021 and a plug 2022 electrically connected to each other. When installing the server 202 to the positioning structure 100, the plug 2022 and connector 203 will be electrically connected to each other.

As shown in FIG. 2 to FIG. 4, in some embodiments, each positioning structure 100 includes a chassis 10, a door 20, a locking piece 30, a handle 40, and a first elastic piece 50. The chassis 10 defines a cavity 111 and a first opening 112 connected to each other, the cavity 111 is used for accommodating a server 202, the first opening 112 allows the server 202 to enter and exit the cavity 111 in a first direction X. The door 20 is rotatably connected to the chassis 10 to open and cover the first opening 112. The locking piece 30 is movably connected to door 20 and is used for locking the door 20. When the door 20 covers the first opening 112, the first elastic piece 50 can move the locking piece 30 into a slot 16 of the chassis 10, to position the door 20 relative to the chassis 10. The handle 40 is movably connected to the door 20, the handle 40 can move the locking piece 30, to unlock the connection between the locking piece 30 and the chassis 10.

When removing the server 202 out of the cavity 111, unlock the door 20 first, then rotate the door 20 to open the first opening 112. When installing the server 202 into the cavity 111, insert the server 202 into the cavity 111 through the first opening 112, then rotate the door 20 to cover the first opening 112 until the locking piece 30 locks the door 20.

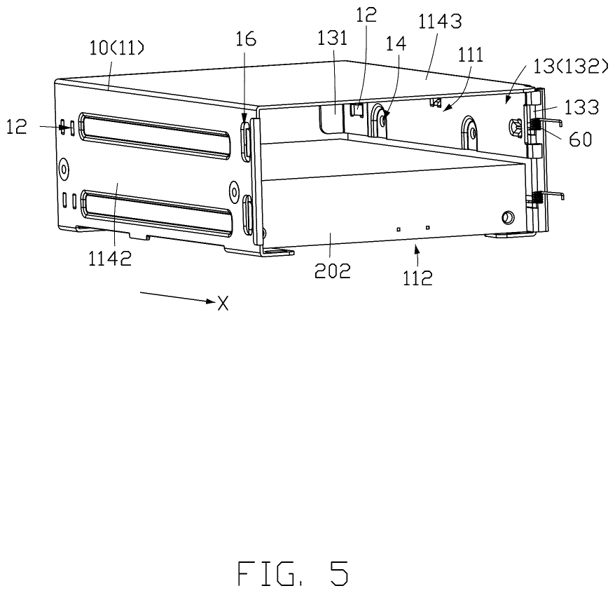

As shown in FIG. 2 and FIG. 5, in some embodiments, the chassis 10 includes a frame 11, the cavity 111 and the first opening 112 are formed on the frame 11, the server 202 can enter the cavity 111 by the first opening 112 in the first direction X.

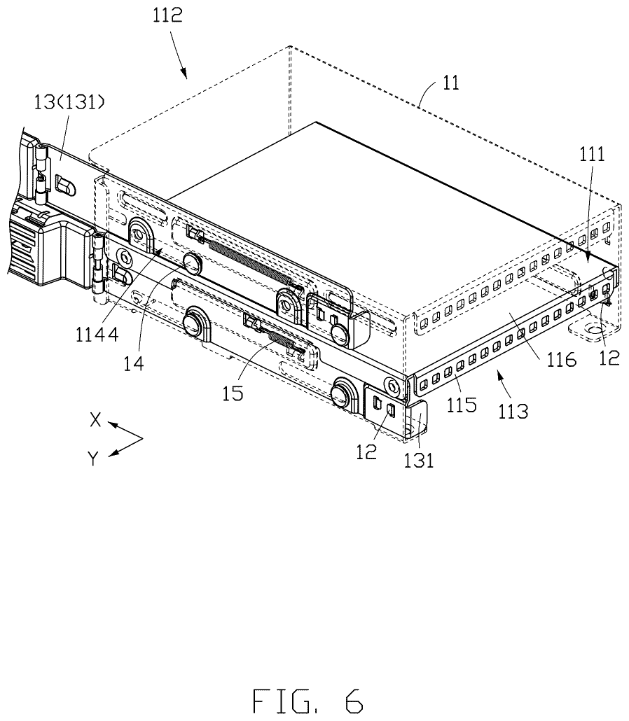

As shown in FIG. 2, FIG. 5 and FIG. 6, in some embodiments, the frame 11 has an avoiding hole 113. During the server 202 enters the cavity 111 through the first opening 112, the plug 2022 passes through the avoiding hole 113 out of the cavity 111 to connect the connector 203.

As shown in FIG. 2 and FIG. 5, in some embodiments, the frame 11 includes frame main body 114 and limiting sheet 115, the avoiding hole 113 is formed between the limiting sheet 115 and the frame 11, the first opening 112 is located on the frame main body 114. The limiting sheet 115 is used for limiting the storage module 2021 from moving outside the cavity 111. When the storage module 2021 is installed in the cavity 111 correctly, the storage module 2021 is against the limiting sheet 115, the plug 2022 extends out of the avoiding hole 113, but when the server 202 is installed upside down, the plug 2022 will be stopped by the limiting sheet 115 form extending out of the avoiding hole 113.

As shown in FIG. 2 and FIG. 5, in some embodiments, the frame main body 114 includes a first wall 1141, a second wall 1142, and a third wall 1143, the first wall 1141 and the second wall 1142 face to each other and located on opposite sides of the third wall 1143, the first wall 1141 and the second wall 1142 are parallel, the first wall 1141 and the third wall 1143 are perpendicular. The first wall 1141 and the second wall 1142 are located on the rack body 201, the cavity 111 and the first opening 112 are formed between the first wall 1141, the second wall 1142, and the third wall 1143.

As shown in FIG. 2 and FIG. 5, in some embodiments, the frame 11 further includes a separating wall 116, the separating wall 116 also has the limiting sheet 115 on an end away from the first opening 112. The separating wall 116 is located between the first wall 1141 and the second wall 1142 and is used for separating two adjacent servers 202.

As shown in FIG. 5, in some embodiments, the frame 11 has a metal spring 12, the metal spring 12 is located on the first wall 1141 or the second wall 1142 and is placed in the cavity 111. When installing the server 202 into the cavity 111, the server 202 contacts the metal spring 12 and presses the metal spring 12, so the server 202 is grounded to prevent electric leakage, and the metal spring 12 can hold the server 202 tight.

As shown in FIG. 2, FIG. 5, and FIG. 6, in some embodiments, the chassis 10 further includes a sliding piece 13, the sliding piece 13 is placed in the cavity 111 and movably located on the frame 11 in the first direction X. The frame 11 can move between a first position and a second position. When the sliding piece 13 is in the first position, the server 202 is outside the cavity 111. When the sliding piece 13 is in the second position, the server 202 is fully inside the cavity 111, and the sliding piece 13 in FIG. 2 and FIG. 5 is in the second position. The upper sliding piece 13 in FIG. 6 is in the first position, the lower sliding piece 13 in FIG. 6 is in the second position. When inserting the server 202 into the cavity 111, the sliding piece 13 moves form the first position to the second position. When removing the server 202, the sliding piece 13 moves from the second position to the first position and pushes the server 202 out of the cavity 111.

As shown in FIG. 2 and FIG. 6, in some embodiments, the sliding piece 13 includes a pushing part 131 and a sliding part 132 connected to each other, the pushing part 131 is located on an end of the sliding part 132 away from the first opening 112. The sliding part 132 is movably located on the frame 11, to let the sliding piece 13 be movable on the frame 11. The pushing part 131 is used for pushing the server 202 out of the cavity 111.

When removing the server 202, unlock the door 20 through the locking piece 30, then rotate the door 20 to open the first opening 112 of the frame 11, and the pushing part 131 pushes the server 202 out of the cavity 111. The above-mentioned “the pushing part 131 pushes the server 202 out of the cavity 111” means a part of the server 202 is out of the cavity 111, not all the server 202 is out of the cavity 111. When inserting the server 202, the server 202 pushes the pushing part 131 so moves the sliding piece 13.

In some embodiments, each cavity 111 can accommodate two servers 202 in two layers, each server 202 corresponds to a door 20 and a sliding piece 13.

As shown in FIG. 2 and FIG. 6, in some embodiments, the chassis 10 further includes a plurality of first connecting pieces 14, the first wall 1141 has plurality of sliding grooves 1144, each first connecting piece 14 extends through each sliding groove 1144 and is slidable in the sliding groove 1144 along the first direction X, and the first connecting piece 14 is connected to the sliding part 132. Each first connecting piece 14 is I-shaped nails. When the sliding part 132 slides, the first connecting piece 14 slides in the sliding groove 1144, to guide the sliding part 132.

As shown in FIG. 6, in some embodiments, the chassis 10 further includes a second elastic piece 15, the second elastic piece 15 is connected to the sliding part 132 and the first wall 1141 of the frame 11. The second elastic piece 15 can deform in the first direction X. When the sliding piece 13 is in the second position, the second elastic piece 15 is in natural state, when the sliding piece 13 is in the first position, the second elastic piece 15 is stretched so the second elastic piece 15 can pull the sliding piece 13 back to the second position.

In some embodiments, the sliding part 132 also has a metal spring 12, the metal spring 12 of the sliding part 132 and the metal spring 12 of the frame 11 correspond to each other in the second direction Y, to press the server 202 for better stability.

As shown in FIG. 1 and FIG. 5, in some embodiments, the chassis 10 has a slot 16, the locking piece 30 can insert into the slot 16, to latch the door 20 for closing the first opening 112. The slot 16 is located on the second wall 1142. The door 20 is rotatably located on the first wall 1141.

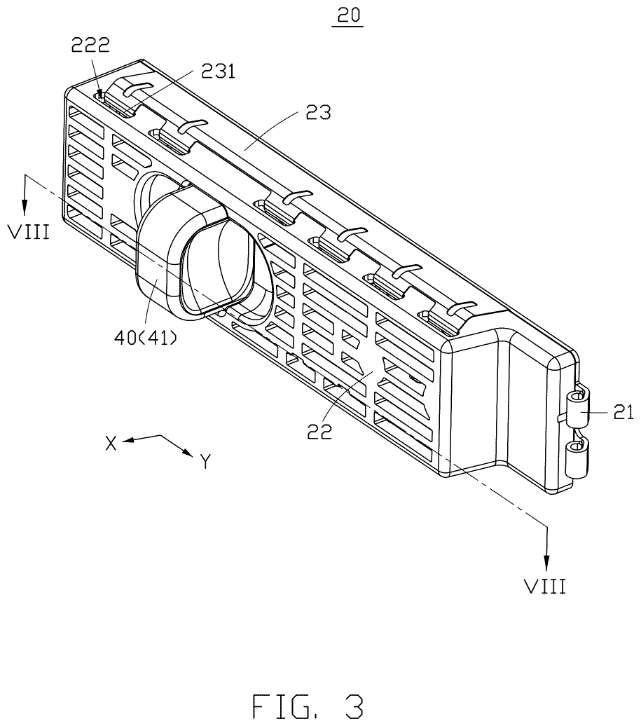

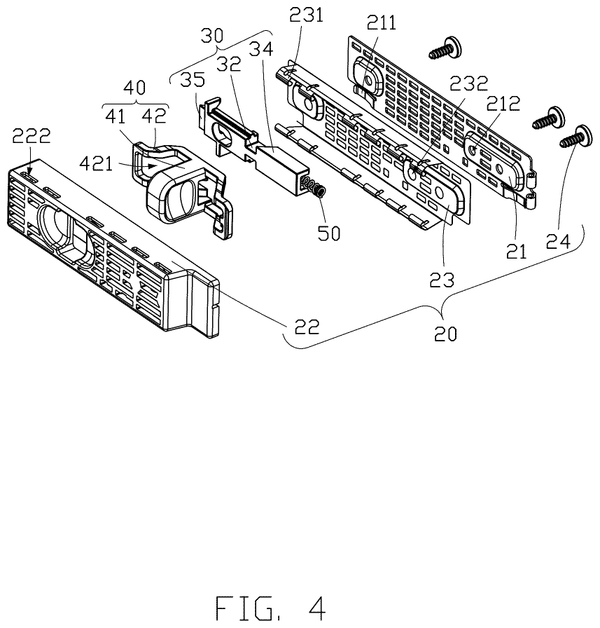

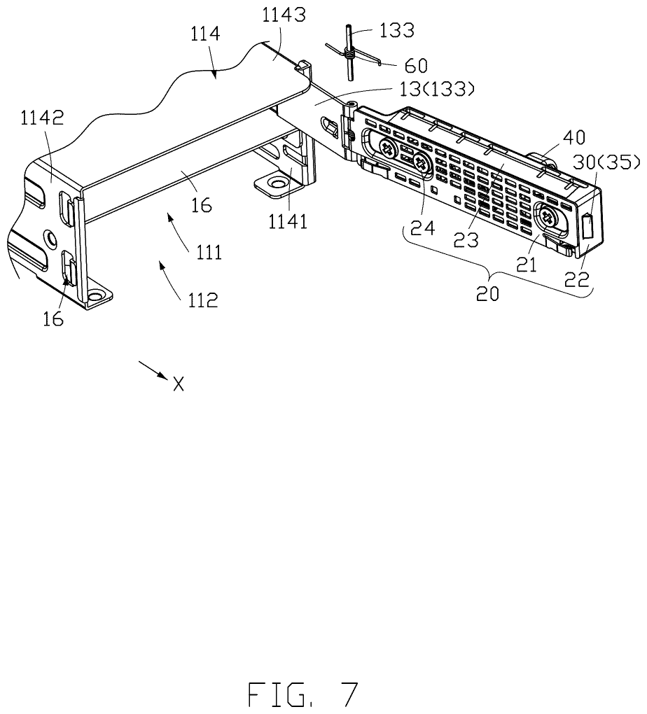

As shown in FIG. 3, FIG. 4, and FIG. 7, in some embodiments, the door 20 includes a first rotating board 21 and a second rotating board 22, the first rotating board 21 is rotatably located on the chassis 10, the second rotating board 22 is located on the first rotating board 21, an installing space is formed between the first rotating board 21 and the second rotating board 22, part of the locking piece 30 and part of the handle main body 41 is in the installing space. The first rotating board 21 and the second rotating board 22 can improve the structural strength of the door 20, and the installing space is easy for installing the handle 40 and the locking piece 30.

Furthermore, the first rotating board 21 is connected to a side of the sliding piece 13 closer to the first opening 112. When the sliding piece 13 moves in the first direction X, moves the door 20 in the first direction X in the meantime, so the door 20 can avoid the server 202.

As shown in FIG. 7, in some embodiments, the first rotating board 21 includes a spring sheet 211, the spring sheet 211 is against the server 202 for better stability.

As shown in FIG. 1 and FIG. 7, in some embodiments, the second rotating board 22 is a box with an opening that faces to the first rotating board 21, to form the installing space with the first rotating board 21. The second rotating board 22 has a first hole 221, the locking piece 30 can extend through the first hole 221 out of the installing space to insert into the slot 16.

As shown in FIG. 3, FIG. 4, and FIG. 7, in some embodiments, the door 20 further includes EMC (Electro Magnetic Compatibility) spring sheet 23, EMC spring sheet 23 is located between the first rotating board 21 and the second rotating board 22. The EMC spring sheet 23 has the ability to avoid electromagnetic interference and be interfered with, which can reduce the electromagnetic interference to the server 202.

The EMC spring sheet 23 includes a bended part 231, the second rotating board 22 has a fixing hole 222, the bended part 231 is in the fixing hole 222, the bended part 231 pushes the second rotating board 22 to the first rotating board 21, for assembling the second rotating board 22 and the EMC spring sheet 23.

In some embodiments, the door 20 has a hollow structure, the server 202 has a light source. After the server 202 is inserted into the cavity 111 and the door 20 closes the first opening 112, the light emitted by the light source can pass through the hollow structure, so that the user can observe the working status of the server 202.

As shown in FIG. 3, FIG. 4, and FIG. 7, in some embodiments, the door 20 further includes a second connecting piece 24, the second connecting piece 24 is located on the first rotating board 21 and extends through the first rotating board 21 and is connected to the second rotating board 22. The second connecting piece 24 is used for assembling the first rotating board 21, the EMC spring sheet 23, and the second rotating board 22.

As shown in FIG. 3, FIG. 4, and FIG. 7, in some embodiments, the second connecting piece 24 is a screw, the second rotating board 22 has a screw hole 223, the first rotating board 21 has a second hole 212, the EMC spring sheet 23 has a third hole 232, the screw extends through the second hole 212 and the third hole 232 to be in the screw hole 223, for assembling the door 20.

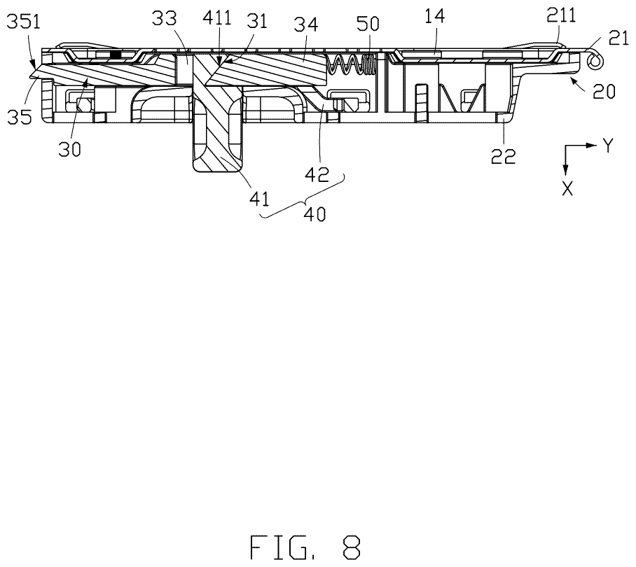

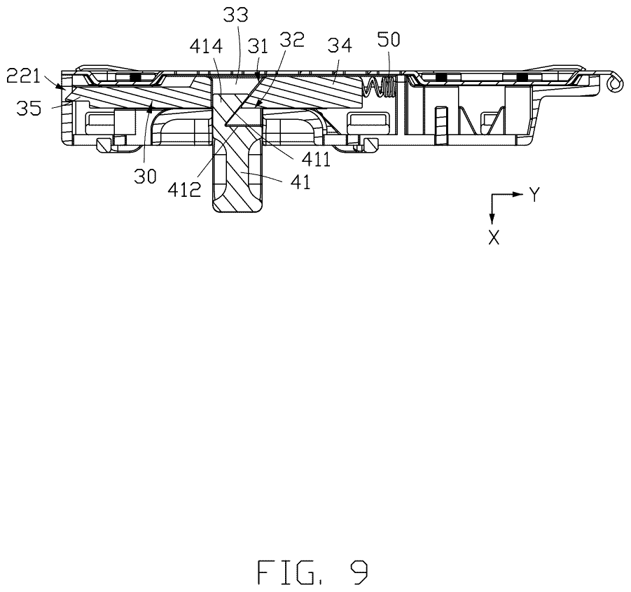

As shown in FIG. 3, FIG. 4, FIG. 8, and FIG. 9, in some embodiments, the locking piece 30 has a first bevel 31. The handle 40 includes a handle main body 41, the handle main body 41 has a second bevel 411, the second bevel 411 and the first bevel 31 are parallel. When the door 20 closes the first opening 112 and the handle main body 41 is away from the chassis 10 in the first direction X, the second bevel 411 pushes the first bevel 31 to move the locking piece 30 in the second direction Y, which is the handle main body 41 moves form the state shown in FIG. 8 to the state shown in FIG. 9, to pull out the locking piece 30 from the slot 16, so the door 20 can open the first opening 112. The second direction Y and the first direction X are perpendicular.

As shown in FIG. 3, FIG. 4, FIG. 8, and FIG. 9, in some embodiments, the locking piece 30 further includes a first stopping surface 32, the handle main body 41 further includes a second stopping surface 412, the first stopping surface 32 and the second stopping surface 412 are parallel. When the locking piece 30 is inserted into the slot 16, the first stopping surface 32 contacts the second stopping surface 412, to limit the handle main body 41 from moving to the chassis 10.

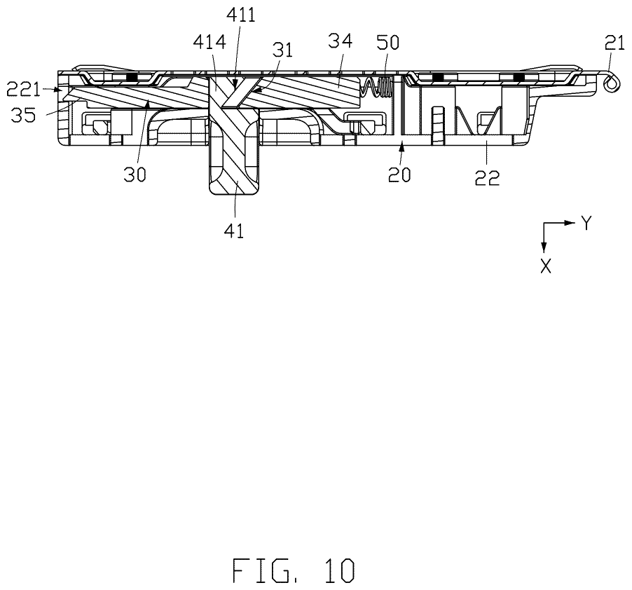

As shown in FIG. 10, when the handle 40 is not subjected to external force, the handle main body 41 is located close to the chassis 10. At this time, the locking piece 30 can move in the second direction Y when subjected to external force, and is not easily affected by the handle main body 41, so that the locking piece 30 can move in the direction away from the slot 16 under the action of external force.

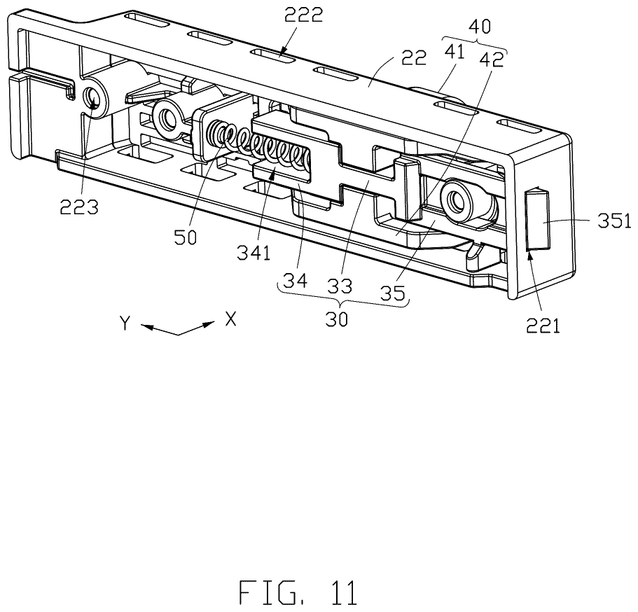

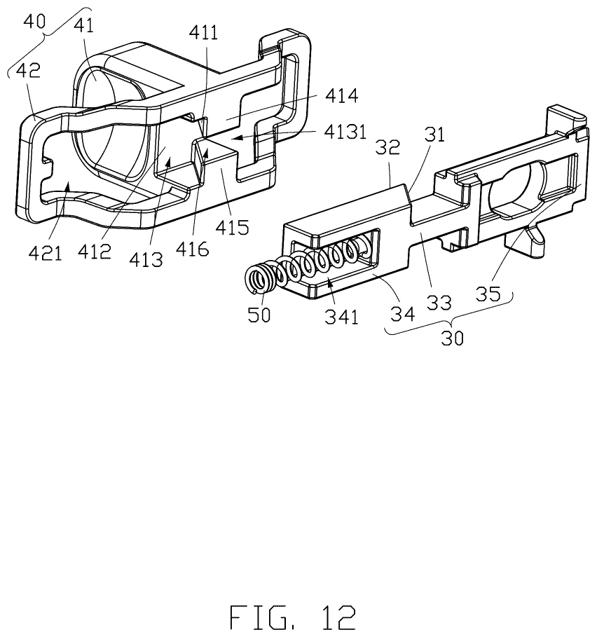

As shown in FIG. 11 and FIG. 12, in some embodiments, the handle main body 41 has an installing groove 413, the installing groove 413 has a second opening 4131 that faces to the chassis 10, the installing groove 413 has a first block 414 and a second block 415, the second bevel 411 is located on the first block 414 and the second block 415, the guiding channel 416 is formed between the first block 414 and the second block 415, the guiding channel 416 and the second opening 4131 are connected to each other.

The locking piece 30 includes a guiding part 33, the guiding part 33 is placed in the guiding channel 416 and is movable in the second direction Y. in the first direction X, the guiding part 33 can move relative to the handle main body 41 from the second opening 4131 to an outside of the guiding channel 416.

The guiding part 33 is movable in the guiding channel 416 can makes it easier to assemble the guiding part 33 and the handle main body 41. The guiding channel 416 and the second opening 4131 are connected, so the guiding part 33 can enter and exit the guiding channel 416 through the second opening 4131, which eases the assembly of the guiding part 33 and the handle main body 41, and eases the movement of the handle main body 41 away from the chassis 10.

As shown in FIG. 11 and FIG. 12, in some embodiments, the locking piece 30 includes an assembling part 34, the assembling part 34 is connected to the guiding part 33, the first stopping surface 32 and the first bevel 31 is located on the assembling part 34, the assembling part 34 is movably located in the installing groove 413. The assembling part 34 has a holding space 341, an end of the first elastic piece 50 is in the holding space 341. The holding space 341 can decrease the volume of the locking piece 30.

As shown in FIG. 7, FIG. 11, and FIG. 12, in some embodiments, the locking piece 30 includes a locking part 35, the locking part 35 is used for inserting into the slot 16, the locking part 35 has a third bevel 351, the third bevel 351 is located on the locking part 35. The locking part 35 is connected to the guiding part 33.

When the door 20 rotates for closing the first opening 112, the third bevel 351 is pressed by the chassis 10, the first elastic piece 50 is compressed, to guide the locking piece 30 moves out of the slot 16, until the locking piece 30 moves to a position where can avoid the chassis 10, the door 20 can move the locking part 35 rotates to a position where is aligned with the slot 16. After the locking part 35 is aligned with the slot 16, the third bevel 351 is no longer pressed by the chassis 10, so the locking part 35 inserts into the slot 16 under the elastic force of the first elastic piece 50.

As shown in FIG. 11 and FIG. 12, in some embodiments, the handle 40 further includes two elastic arms 42, the two elastic arms 42 is located on the handle main body 41, each elastic arm 42 is connected to the handle main body 41 and the door 20. When the handle main body 41 moves away from the chassis 10, the two elastic arms 42 deform, to be able to move the handle main body 41 to the chassis 10. When release the handle main body 41, the handle main body 41 will move to the chassis 10 automatically by the elastic arms 42, to keep the locking piece 30 in the slot 16.

As shown in FIG. 11 and FIG. 12, in some embodiments, each elastic arms 42 has a connecting hole 421, the locking piece 30 is placed in the connecting hole 421 and is movable in the second direction Y, to guide the locking piece 30 to move in the second direction Y.

As shown in FIG. 11 and FIG. 12, in some embodiments, the first elastic piece 50 is connected to the locking piece 30 and the door 20. The first elastic piece 50 is used for inserting the locking piece 30 into the slot 16 and keeping the locking piece 30 in the slot 16.

In some embodiments, the first elastic piece 50 is connected to the assembling part 34 and the second rotating board 22. When the locking piece 30 moves in the second direction Y, the first elastic piece 50 is compressed, when the handle main body 41 releases the locking piece 30, the locking piece 30 moves under the elastic force of the first elastic piece 50 to insert into the slot 16. The first elastic piece 50 is a spring.

As shown in FIG. 5 and FIG. 7, in some embodiments, the positioning structure 100 further includes a third elastic piece 60, the third elastic piece 60 is located on the chassis 10 and is connected to the door 20, the third elastic piece 60 is used to rotate the door 20 to open the first opening 112.

As shown in FIG. 5 and FIG. 7, in some embodiments, the first elastic piece 50 is a torsion spring, the sliding part 132 has an axis 133, the torsion spring is located on the axis 133, the torsion spring is against the first rotating board 21 and the sliding part 132. The first rotating board 21 is rotatable around the axis 133. When rotate the door 20 to open the first opening 112, the torsion spring is compressed, so to rotate the door 20 to close the first opening 112 when release the door 20.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A positioning structure configured for a server, the positioning structure comprising:
a chassis defining a cavity configured for accommodating the server and a first opening configured for the server moving into or out of the cavity in a first direction;
a door rotatably connected to the chassis and configured for opening or covering the first opening;
a locking piece movably connected to the door, the locking piece comprising a first bevel;
a first elastic piece connected to the locking piece and the door; and
a handle movably connected to the door, the handle comprising a handle main body, the handle main body comprising a second bevel contacting the first bevel in parallel,
wherein when the door covers the first opening, the first elastic piece moves the locking piece into a slot of the chassis to position the door, when the door covers the first opening and the handle main body moves away from the chassis in the first direction, the second bevel moves the locking piece by pushing the first bevel in a second direction perpendicular to the first direction, and the locking piece moves out of the slot so that the door can be opened.

2. The positioning structure of claim 1, wherein the locking piece further comprises a first stopping surface, the handle main body further comprises a second stopping surface, the first stopping surface is parallel to the second stopping surface, when the locking piece is moved into the slot, the first stopping surface contacts the second stopping surface to stop the handle main body from moving towards the chassis.

3. The positioning structure of claim 1, wherein the handle further comprises two elastic arms, the two elastic arms are located on opposite sides of the handle main body in the second direction, respectively, each one of the two elastic arms is connected to the handle main body and the door; when the handle main body moves away from the chassis, the two elastic arms elastically deform and cooperatively move the handle main body towards the chassis.

4. The positioning structure of claim 3, wherein each one of the two elastic arms defines a connecting hole, the locking piece is placed in the connecting hole of each of the two elastic arms and is movable in the second direction.

5. The positioning structure of claim 4, wherein the handle main body defines a installing groove, the installing groove defines a second opening facing to the chassis, a first block and a second block are defined in the installing groove, the second bevel is formed on the first block and the second block, a guiding channel is formed between the first block and the second block, the guiding channel is connected to the second opening, the locking piece comprises a guiding part, the guiding part is placed in the guiding channel and movable in the second direction, the guiding part is further movable in the first direction relative to the handle main body.

6. The positioning structure of claim 1, wherein the locking piece comprises a locking part, the locking part is insertable into the slot, the locking part defines a third bevel, the third bevel is located on a side of the locking part towards the chassis.

7. The positioning structure of claim 1, wherein the door comprises a first rotating board and a second rotating board, the first rotating board is rotatably connected to the chassis, the second rotating board is located on the first rotating board, an installing space is formed between the second rotating board and the first rotating board, a part of the locking piece and a part of the handle main body is placed in the installing space.

8. The positioning structure of claim 7, wherein the chassis comprises a frame and sliding piece, the cavity and the first opening are formed in the frame, the sliding piece is located on the frame and movable in the first direction, a pushing part is formed on an end of the sliding piece away from the first opening, the pushing part is configured for pushing the server out of the cavity.

9. A rack comprising:
a rack body; and
a positioning structure configured for positioning a server on the rack body, the positioning structure comprising:
a chassis defining a cavity configured for accommodating the server and a first opening configured for the server moving into or out of the cavity in a first direction;
a door rotatably connected to the chassis and configured for opening or covering the first opening;
a locking piece movably connected to the door, the locking piece comprising a first bevel;
a first elastic piece connected to the locking piece and the door; and
a handle movably connected to the door, the handle comprising a handle main body, the handle main body comprising a second bevel contacting the first bevel in parallel,
wherein when the door covers the first opening, the first elastic piece moves the locking piece into a slot of the chassis to position the door, when the door covers the first opening and the handle main body moves away from the chassis in the first direction, the second bevel moves the locking piece by pushing the first bevel in a second direction perpendicular to the first direction, and the locking piece moves out of the slot so that the door can be opened.

10. The rack of claim 9, wherein the locking piece further comprises a first stopping surface, the handle main body further comprises a second stopping surface, the first stopping surface is parallel to the second stopping surface, when the locking piece is moved into the slot, the first stopping surface contacts the second stopping surface to stop the handle main body from moving towards the chassis.

11. The rack of claim 9, wherein the handle further comprises two elastic arms, the two elastic arms are located on opposite sides of the handle main body in the second direction, respectively, each one of the two elastic arms is connected to the handle main body and the door; when the handle main body moves away from the chassis, the two elastic arms elastically deform and cooperatively move the handle main body towards the chassis.

12. The rack of claim 11, wherein each one of the two elastic arms defines a connecting hole, the locking piece is placed in the connecting hole of each of the two elastic arms and is movable in the second direction.

13. The rack of claim 12, wherein the handle main body defines a installing groove, the installing groove defines a second opening facing to the chassis, a first block and a second block are defined in the installing groove, the second bevel is formed on the first block and the second block, a guiding channel is formed between the first block and the second block, the guiding channel is connected to the second opening, the locking piece comprises a guiding part, the guiding part is placed in the guiding channel and movable in the second direction, the guiding part is further movable in the first direction relative to the handle main body.

14. The rack of claim 9, wherein the locking piece comprises a locking part, the locking part is insertable into the slot, the locking part defines a third bevel, the third bevel is located on a side of the locking part towards the chassis.

15. The rack of claim 9, wherein the door comprises a first rotating board and a second rotating board, the first rotating board is rotatably connected to the chassis, the second rotating board is located on the first rotating board, an installing space is formed between the second rotating board and the first rotating board, a part of the locking piece and a part of the handle main body is placed in the installing space.

16. The rack of claim 15, wherein the chassis comprises a frame and sliding piece, the cavity and the first opening are formed in the frame, the sliding piece is located on the frame and movable in the first direction, a pushing part is formed on an end of the sliding piece away from the first opening, the pushing part is configured for pushing the server out of the cavity.

17. A computing device comprising:
a plurality of servers; and
a rack comprising:
a rack body; and
a plurality of positioning structures configured for positioning the plurality of servers on the rack body, each of the plurality of positioning structures comprising:
a chassis defining a cavity configured for accommodating each of the plurality of servers and a first opening configured for each of the plurality of servers moving into or out of the cavity in a first direction;
a door rotatably connected to the chassis and configured for opening or covering the first opening;
a locking piece movably connected to the door, the locking piece comprising a first bevel;
a first elastic piece connected to the locking piece and the door; and
a handle movably connected to the door, the handle comprising a handle main body, the handle main body comprising a second bevel contacting the first bevel in parallel,
wherein when the door covers the first opening, the first elastic piece moves the locking piece into a slot of the chassis to position the door, when the door covers the first opening and the handle main body moves away from the chassis in the first direction, the second bevel moves the locking piece by pushing the first bevel in a second direction perpendicular to the first direction, and the locking piece moves out of the slot so that the door can be opened.

18. The computing device of claim 17, wherein the locking piece further comprises a first stopping surface, the handle main body further comprises a second stopping surface, the first stopping surface is parallel to the second stopping surface, when the locking piece is moved into the slot, the first stopping surface contacts the second stopping surface to stop the handle main body from moving towards the chassis; the locking piece comprises a locking part, the locking part is configured for being inserted into the slot, the locking part defines a third bevel, the third bevel is located on a side of the locking part towards the chassis.

19. The computing device of claim 17, wherein the handle further comprises two elastic arms, the two elastic arms are located on opposite sides of the handle main body in the second direction, respectively, each one of the two elastic arms is connected to the handle main body and the door; when the handle main body moves away from the chassis, the two elastic arms elastically deform and cooperatively move the handle main body towards the chassis, each one of the two elastic arms defines a connecting hole, the locking piece is placed in the connecting hole of each of the two elastic arms and is movable in the second direction, the handle main body defines a installing groove, the installing groove defines a second opening facing to the chassis, a first block and a second block are defined in the installing groove, the second bevel is formed on the first block and the second block, a guiding channel is formed between the first block and the second block, the guiding channel is connected to the second opening, the locking piece comprises a guiding part, the guiding part is placed in the guiding channel and movable in the second direction, the guiding part is further movable in the first direction relative to the handle main body.

20. The computing device of claim 17, wherein the door comprises a first rotating board and a second rotating board, the first rotating board is rotatably connected to the chassis, the second rotating board is located on the first rotating board, an installing space is formed between the second rotating board and the first rotating board, a part of the locking piece and a part of the handle main body is placed in the installing space, the chassis comprises a frame and sliding piece, the cavity and the first opening are formed in the frame, the sliding piece is located on the frame and movable in the first direction, a pushing part is formed on an end of the sliding piece away from the first opening, the pushing part is configured for pushing the server out of the cavity.
